(19) United States
(12) Patent Application Publication
(10) Pub. No.: US 2023/0128755 A1
(43) Pub. Date: Apr. 27, 2023

(54) HERMETICALLY SEALED PACKAGE AND METHOD FOR PRODUCING SAME

(71) Applicant: Schott AG, Mainz (DE)

(72) Inventors: Antti Määttänen, Tampere (FI); Jens Ulrich Thomas, Mainz (DE)

(73) Assignee: Schott AG, Mainz (DE)

(21) Appl. No.: 18/088,035

(22) Filed: Dec. 23, 2022

Related U.S. Application Data
(63) Continuation of application No. PCT/EP2021/067877, filed on Jun. 29, 2021.

(30) Foreign Application Priority Data
Jun. 30, 2020 (DE) 10 2020 117 194.3

(51) Int. Cl. B81B 7/00; B81C 1/00

(52) U.S. Cl. CPC B81B 7/0041; B81C 1/00269; B81B 2201/0214; B81C 2203/0145; B81C 2203/0118; B81C 2203/036

(57) ABSTRACT

A hermetically sealed package includes: at least one cover substrate which is sheet-like and includes a flat outer surface and a circumferential narrow side, the at least one cover substrate being formed as a transparent thin film substrate, the at least one cover substrate having a thickness of less than 200 μm; a second substrate which is adjoined to the at least one cover substrate and in direct contact with the at least one cover substrate; at least one functional area enclosed by the hermetically sealed package, the at least one functional area being between the at least one cover substrate and the second substrate; and a laser bonding line which joins the at least one cover substrate and the second substrate directly and in a hermetically tight manner.

### CROSS REFERENCE TO RELATED APPLICATIONS

This is a continuation of PCT application no. PCT/EP2021/067877, entitled “HERMETICALLY SEALED ENCLOSURE AND METHOD FOR THE PRODUCTION THEREOF”, filed Jun. 29, 2021, which is incorporated herein by reference. PCT application no. PCT/EP2021/067877 claims priority to German patent application no. DE 10 2020 117 194.3, filed Jun. 30, 2020, which is incorporated herein by reference.

### BACKGROUND OF THE INVENTION

### 1. Field of the Invention

The present invention relates to a hermetically sealed package, to a substrate assembly, and to a method for providing a hermetically sealed package.

### 2. Description of the Related Art

Hermetically sealed packages are intended to protect a component or components inside the package from adverse environmental conditions, for example. By way of example, sensitive electronics, circuits, or sensors accommodated inside the package can be protected in this way. This allows to implement and apply sensors or medical implants, for example in the area of the heart, in the retina, or for bioprocessors. They can also be used as MEMSs (micro-electro-mechanical systems), barometers, blood gas sensors, glucose sensors, etc., for example. Known and utilized bioprocessors are made from titanium.

Since the aforementioned requirements for protecting the electronics housed in a package are imposed on a package, certain fields of application have so far been ruled out for the use of a package, including requirements for which a particularly thin package would be necessary, or at least one thin side of the package. These include, for example, a fingerprint sensor, contact lenses with variable focus, neuralgic pressure sensors for intracorporeal use, such as for measuring intracranial pressure, or the ultra-thin encapsulation of image sensors. For these areas of application, too, it can be advantageous to appropriately protect the electronics against adverse environmental influences. In particular optical communication with the interior of the package can advantageously be ensured here. For this purpose, the package can be designed so as to be transparent at least partially, i.e. at least in certain areas and/or at least for a range of wavelengths. This transparency furthermore provides for communication processes, for example, for data or power transfer, for measurements by and with the electronics or the sensor disposed in the cavity. In particular optical communication processes or optical data or power transfer can be enabled.

However, it is complicated or may even be impossible to take a thin substrate per se and place it on a package. Thin substrates tend to bulge when they are combined with further substrate layers. This can also change the physical properties of the thin substrate, such as thermal conductivity. Furthermore, thin substrates can exhibit high internal stress that makes them unsuitable for the fabrication of a package. Joining processes involving lasers cannot be applied with thin substrates since material will be burned or removed if the laser is targeted too close to the surface of the thin substrate, for example. It has therefore been difficult or even impossible to use thin substrates for producing a package which at the same time is particularly well hermetically sealed and/or can be joined without the use of additional bonding materials.

In principle, it has been known to join a plurality of parts and to arrange these parts such that an accommodation area is created in an intermediate space, which can accommodate components. For example, European patent document EP 3 012 059 B1 discloses a method for producing a transparent piece for protecting an optical component. A novel laser process is used for this purpose.

What is needed in the art is an improvement of packages.

### SUMMARY OF THE INVENTION

Further fields of application for a package according to the present invention can be found in electronic applications such as for a case of a smartphone, in the field of virtual reality glasses and similar devices. A package according to the present invention can also be used for the production of flow batteries, for example in the context of electro-mobility. However, packages according to the present invention can also find application in the aerospace industry, in high-temperature applications, and in the field of micro-optics.

The present invention can be considered as improving prior art packages and in particular enhancing the exchange with an interior of the package. More particularly, to the present invention improves optical exchange with the interior of the package or else a sensitivity for the external environment of the package, such as pressure sensitivity. Optionally, the package of the present invention allows to use less expensive components and/or a more sensitive measurement of environmental data. At the same time, the packages of the present invention are as reliable and durable as prior art packages.

A hermetically sealed package according to the present invention includes at least one sheet-like cover substrate, which cover substrate has a flat outer surface and a circumferential narrow side. In other words, the cover substrate has an outer surface facing the environment, which is essentially planar or flat. A circumferential narrow side extends adjacent to the flat outer surface and is typically oriented at a right angle to the flat outer surface, for example so as to extend around the edge of the flat outer surface. In one example, the cover substrate can be described as a panel or cuboid which has two large-area sides or faces and four smaller sides extending between the large-area faces, in particular perpendicular to the two large-area faces and adjoining the large-area faces. Thus, the four smaller sides jointly define the circumferential narrow side, and the upper face defines the flat outer surface of the cover substrate. The upper surface typically has a larger surface area than the smaller sides of the circumferential narrow side together.

The hermetically sealed package furthermore includes a second substrate that is arranged so as to adjoin the cover substrate and to be in direct contact with the sheet-like cover substrate. The second substrate and the cover substrate together define at least part of the package. Optionally, the two substrates are arranged on top of one another, that is they are stacked. For example, the substrates jointly form a substrate stack. Orientation terms like above or below are only meant to be descriptive, since the substrates can assume any orientation in space, as a matter of course, and even an arrangement next to one another should not depart from the scope of protection. Typically, the two substrates are placed with their major sides, or faces, abutting one another.

The package furthermore includes a functional area which is enclosed by the package and which is in particular provided between the cover substrate and the second substrate. For example, the functional area is a cavity or an active layer.

Furthermore, the package includes a laser bonding line which joins the cover substrate and the second substrate that adjoins the cover substrate directly and in a hermetically tight manner. A laser bonding line typically has a height HL perpendicular to its bonding plane. The laser bonding line optionally extends into the material of the substrate arranged above the laser bonding line over the height HL. On the opposite side, the laser bonding line extends into the material of the substrate lying under the laser bonding line. The cover substrate is directly joined to the second substrate, for example by being fused thereto, without having to use adhesion promoters or adhesives, for example. The laser bonding line can also be physically targeted into one of the two substrates to be joined, i.e. the target point of the laser can be located in one of the two substrates, while the laser bonding line will always extend into the two substrates to be joined. During the joining or welding step or in the laser bonding line, material from one substrate and material from the other substrate melts and mixes to produce the firm and non-detachable hermetic bond between the one substrate and the other substrate.

If the package only consists of the cover substrate and the second substrate to form the package as a whole, the cover substrate is directly joined to the second substrate, and the package will include one laser bonding line. In this case, the package has a bonding plane or joining area, where substrates are joined to one another. In a further example, the package can be defined by three substrates stacked on top of one another, in which case the cover substrate will be directly joined to the second substrate, and the second substrate will be joined to a base substrate which also defines a bottom of the package. In this example, the package has two contact zones or two joining areas along which the package is joined.

The package includes the cover substrate in the form of a transparent thin film substrate, the cover substrate having a thickness of less than 200 μm. Such a thin film substrate provides all the advantages that a conventional package is also able to provide, namely in particular the hermetic sealing of the interior of the package from the environment as well as the chemical inertness of the package, which is particularly advantageous for intracorporeal utilization. Moreover, the use of a package according to the present invention also opens up fields of application where conventional packages could previously not be used. For example, a pressure sensor can be designed to be more sensitive, and it becomes possible to implement particularly precise optical data transfers such as necessary for a fingerprint sensor, for example.

A package typically defines a cavity, i.e. a hollow space, in an interior of the package. For example, the cavity has a lateral circumferential edge, a bottom, and an upper side, where the cavity is enclosed by the package. In other words, the cavity is enclosed by the package all around, so that the inner surface of the package at the same time defines the borders of the cavity, if exactly one cavity is provided in the package. In the case of two or more cavities in the package, the two or more cavities are jointly enclosed by the package.

For the purposes of the present application, bottom and upper side is a geometrical construct which may also be any other side with regard to the final orientation of the package. Alternatively, the upper side may be described as a first side, the bottom side as a second side opposite the first side, and the edge as the intermediate area between the first and second sides, with the edge typically extending substantially perpendicular to the first and/or second sides. The lateral circumferential edge typically connects the first side to the second side.

If the cavity is in the form of an accommodation cavity, it will contain an accommodated component disposed therein, for example. This may include electronic circuits, sensors, or an MEMS (micro-electromechanical system), or an MOEMS (microoptoelectromechanical system).

The substrates are arranged directly next to one another or on top of one another. This means that the at least two substrates are arranged or attached to one another in such a way that they make surface contact without providing or introducing any other materials or layers between the at least two substrates. For technical reasons, there might be minor gas inclusions or impurities such as dust particles between the substrate layers, which cannot be avoided. This may be a result of possible unevenness between the substrate layers or on the surfaces of the substrate layers, although in the micro range. Optionally, such a spacing or gap that may be present between the substrates is less than or equal to 5 μm, optionally less than or equal to 1 μm. In a further optional embodiment, the joining zone or laser bonding line produced by the laser has a thickness between 10 μm and 50 μm. The laser bonding line thus ensures hermetic sealing, as it safely bridges any gap that might exist between the two substrates.

One of the laser bonding lines or the one laser bonding line may enclose the functional area circumferentially at a distance DF therefrom. The distance DF may be consistent circumferentially around the functional area, so that the laser bonding line is arranged all around the functional area at approximately the same distance therefrom. The distance DF may also vary, depending on the application, which might be more favorable in terms of production technology, as the case may be, for example if a plurality of packages are joined in a common processing step, or if the functional area has a round or arbitrary shape and the laser bonding line is drawn as a straight line. In the case where the cavity has optical properties, for example if it is in the form of a lens such as a converging lens, the laser bonding line can also be formed around the cavity and optionally at different distances from the cavity. A package may also include a plurality of cavities.

At the contact area between the at least two substrates, the package or the contact area may be optically transparent or may else be opaque in the visible wavelength range. Only the substrate through which the laser used for the joining process passes to form the laser bonding line has at least one spectral window, so that at least the wavelength of the employed laser can pass through the substrate at least partially or at least in sections thereof. The contact area is therefore adapted such that energy deposition can be introduced there using a laser welding process. The laser is thus at least partially absorbed there. This can be achieved locally in such a way that the laser welding process can be referred to as a cold joining process, which means that the thermal energy provided for the joining is introduced in a focused manner into the area of the laser bonding line and diffuses only comparatively slowly into the remaining material of the package, so that in particular no significant temperature rise occurs in the functional area.

Thereby, the laser locally melts material of the two substrates at least partially in the area of the bonding line, so that the at least two substrates are bonded locally. For this matter, a person skilled in the art may refer to EP 3 012 059 B1, for example, which is hereby incorporated by reference.

The cover substrate may have a thickness of less than 170 μm. Optionally, the cover substrate has a thickness of 150 μm or less, optionally 125 μm or less. The cover substrate can furthermore have a thickness of 10 μm or more, optionally 20 μm or more. In other words, the thickness of the cover substrate optionally ranges from 10 μm to 170 μm, for example optionally from 20 μm to 150 μm.

If the package is used as a pressure sensor, an advantageous thickness of the cover substrate 3 may be in the range from 100 μm to 150 μm. In principle, a thinner substrate thickness of the cover substrate 3 allows to achieve higher sensitivity, in particular for optical measurements or pressure measurements (for example also for pressure measurements that are based on changes in the optical property of the cover substrate 3). However, a lower limit for the thickness of the cover substrate 3, in particular for a portion 3a that spans a cavity 2, can be determined on the basis of spontaneous material failure or decreasing resistance to impact or pressure loads as the material thickness decreases. From this, a range from 100 μm to 150 μm has been derived to be very useful for the present applications.

Furthermore, the thickness of the cover substrate 3 can also depend on the area or the size of the cavity 2 to be covered. For example, the cavity has an area that is spanned by the cover substrate. This area of the cavity or of the functional area may, for example, be in the range from 1×10⁻⁴ to 1×10⁻⁸ m², optionally from 1×10⁻⁵ to 1×10⁻⁷, and can optionally be 1×10⁻⁶ plus/minus one order of magnitude. In other words, the area of the cavity or of the functional area is 1×10⁻⁴ m² or smaller, optionally 1×10⁻⁵ or smaller, optionally about 1×10⁻⁶ or smaller. Furthermore, the area of the cavity or of the functional area is 1×10⁻⁸ or larger, optionally 1×10⁻⁷ or larger, optionally about 1×10⁻⁶ or larger.

A cover substrate for a package may, for example, define a ratio of thickness of the cover substrate 3 to area of the functional area 18 or cavity 2, and this ratio is in the range from 0.5 to 20,000, optionally in the range from 1 to 10,000, optionally from 5 to 1,000, optionally from 10 to 100. If the functional area can be covered in a supported manner, i.e. if the portion 3a is not self-supporting, the ratio of thickness of the cover substrate 3 to the area of functional area 18 can be particularly small, since sagging is not expected.

The laser bonding line has a width B in a direction parallel to the planar extension direction of the cover substrate. The width W is in particular measured at the surface of the cover substrate, that is the flat outer surface.

In the state bonded to the substrate, the cover substrate has a surprising and unforeseeable increased shear strength. Optionally, the shear strength of the cover substrate is increased specifically because it is bonded to the second substrate by the laser bonding line adapted according to the present invention. In other words, the increased shear strength is specifically achieved because the cover substrate is initially provided in a thicker form and is joined to the adjoining substrate in this thicker form using the laser. The laser bonding line that is formed as a result differs from a laser bonding line that would be obtained if the cover substrate were already provided in the form of a thin film substrate and was to be joined using the laser. In fact, in this case, the introduction of the laser bonding line into the material of the cover substrate (i.e. also the target point of the laser) would be so close to the flat outer surface that the flat outer surface would be damaged or altered by the laser, and an enhancement of the cover substrate would just not be achieved.

The laser bonding line in particular forms part of the outer surface of the cover substrate as a result of providing and joining the cover substrate in the form of a thicker substrate and then ablating the thickness, for example by an abrasive process. If the laser bonding line forms part of the outer surface of the cover substrate, or, in other words, if the laser bonding line extends as far as to the outer surface of the cover substrate, this allows to lower or relieve material stresses in the cover substrate in a particularly advantageous manner. For example, the reduction in stress may be brought about by the advantageous combination during the material removal, i.e. for example the polishing of the surface. For example, the laser welding and ablation of material, possibly the combination of the two steps, allows to reduce the stress prevailing in the material of the cover substrate by at least 15%, advantageously by at least 25%, optionally by at least 50%, and possibly even by 65% or more. In other words, the thinned cover substrate exhibits even less stress than a thin film substrate that is bonded in a different way, for example by gluing. As a result, the cover substrate can exhibit better dimensional stability, and/or it can tolerate a greater degree of deflection without breaking, and it can also be more impact-resistant if necessary.

Optionally, the package has a coating layer on the flat outer surface. In other words, the flat outer surface is coated, for example in order to improve optical properties.

The flat outer surface may be provided with a nano-print or nano-embossment. Furthermore, an outer functional area may be provided on the flat outer surface. By way of example, AR coatings, protective coatings, bioactive films, optical filters, conductive layers such as made of ITO or gold, can be employed as a coating layer. Since the coating can advantageously be applied after the joining step, it is not necessary to consider the coating layer needs to be designed so that the laser can pass therethrough.

The flat inner surface, that is to say the side of the first substrate facing the second substrate may have a coating layer as well. If this inner coating layer is provided or applied over the entire surface area, it can become part of the laser bonding line in the area of the laser bonding line. The coating layer may also be provided in a partially covering form, i.e. only covering a section of the flat inner surface. An example for the application of a coating layer on both sides is an anti-reflection coating that is applied on both sides of the first substrate at least partially or in sections thereof.

The cover substrate and/or the second substrate or further substrates can be wafers or can be cut out of wafers, for example made of glass, glass ceramic, silicon, sapphire, or a combination of the aforementioned materials. The material of the second substrate can be different from the material of the cover substrate. It is particularly advantageous if the material of the package is chemically inert, for which borosilicate glass is distinguished, for example. One of the substrates or the substrates can also include or be made of Al₂O₃, sapphire, Si₃N₄, or AlN.

The flat outer surface of the cover substrate is optionally designed to be flat, in particular planar. This means that the flat outer surface in particular has no bulges, and furthermore in particular exhibits a maximum deviation from a flat plane of less than 5 μm. More particularly, the flat outer surface has an average roughness value Ra of less than or equal to 20 nm.

The cover substrate is optionally thinner than 200 μm across its entire extent. Furthermore, the cover substrate optionally has an overall planar shape and consistently has the thickness of the circumferential narrow side across its extent.

The hermetically sealed package optionally defines a contact plane or a contact area of the cover substrate to the second substrate, where the cover substrate contacts the second substrate. The contact plane is optionally free of foreign materials, i.e. free of bonding materials such as, in particular, adhesives or glass frit. In other words, the cover substrate is in direct contact adjoining the second substrate, without any foreign matter interposed therebetween.

The adjoining second substrate may be in the form of a base substrate, in which case the base substrate is hermetically joined to the cover substrate by the same laser bonding line.

The second substrate may also be in the form of an intermediate substrate which is interposed between the cover substrate and a base substrate, and in this case the base substrate will be joined to the intermediate substrate in a first bonding plane, and the cover substrate will be joined to the intermediate substrate in a second bonding plane.

The at least one laser bonding line has a thickness in a direction perpendicular to the planar extension direction of the cover substrate. The thickness of the laser bonding line perpendicular to the planar extension direction of the cover substrate defines the joining zone of the package. Here, the laser bonding line extends as far as to the flat outer surface, and, more particularly, the laser bonding line forms part of the flat outer surface. In other words, the laser bonding line partially extends through the flat outer surface.

In the area of the laser bonding line, a material modification of the cover substrate and/or of the adjoining second substrate is optionally existent. This material modification may include a change in the refractive index and/or a modified chemical composition. This modification optionally forms part of the flat outer surface.

A ratio of the width W of the laser bonding line to the thickness D of the cover substrate, W:D, can be greater than or equal to 1, in particular W:D is greater than or equal to 0.5. Furthermore, the thickness ratio can also be specified as W:D greater than or equal to 0.1, or else W:D greater than or equal to 0.05.

The functional area optionally includes a hermetically sealed accommodation cavity, in an optional embodiment for accommodating an accommodation item such as an electronic circuit, a sensor, or an MEMS or MOEMS.

The cover substrate is optionally transparent for a range of wavelengths, at least partially and/or at least in a section thereof.

Furthermore encompassed by the scope of the present invention is a hermetically joined substrate assembly, in particular for a package as described above. The hermetically joined substrate assembly includes at least one sheet-like substrate having a flat outer surface and a circumferential narrow side, and a second substrate arranged so as to adjoin the first substrate and in direct contact with the sheet-like first substrate. Thus, the second substrate is in physical contact with the first substrate, and this physical contact exists where the laser bonding line bonds the first substrate to the second substrate. If a cavity is intended or provided, the substrates do not necessarily make physical contact in the area of the cavity.

The first substrate of the substrate assembly is in the form of a transparent thin film substrate, the first substrate having a thickness of less than 200 μm.

The substrate assembly furthermore includes a laser bonding line which joins the first substrate and the second substrate that adjoins the first substrate directly and in a hermetically tight manner. The laser bonding line extends as far as to the flat outer surface, more particularly the laser bonding line forms part of the flat outer surface.

Also within the scope of the present invention is a method for providing a hermetically sealed package, in particular a package as described above. The package includes a functional area, and the functional area is in particular in the form of an accommodation cavity for accommodating at least one accommodation item. The method includes the step of providing at least one cover substrate and a second substrate, wherein the cover substrate includes a transparent material. The at least two substrates are arranged directly next to one another or on top of one another, so that a contact zone or a contact area is defined between the at least two substrates. The cover substrate has a flat outer surface and a circumferential narrow side.

The at least two substrates are sealed in a hermetically tight manner by directly joining the at least two substrates to one another along the at least one contact area of the package. More particularly, the accommodation cavity or the functional area is hermetically sealed in this way, optionally by a laser bonding line around the functional area or the accommodation cavity.

Furthermore, the method includes ablating material from the cover substrate, in particular in order to reduce the thickness of the cover substrate. The material is in particular removed abrasively from the cover substrate, for example by sanding or sandblasting, and as a result thereof a thin film substrate is produced from the cover substrate, which has a circumferential narrow side with a thickness of less than 200 μm.

In other words, the method presented in this application makes it possible in the first place to achieve abrasive thinning or ablation of the cover substrate without the cover substrate getting sheared off or detaching or even getting destroyed in the process. This enables significant improvement in the manufacturing process and allows for the manufacture of significantly improved packages.

Here, the distance from the target point of the laser, i.e., the site of non-linear energy input into the package, is of particular importance. This distance T is selected to be large enough so that the material modification introduced by the laser is kept inward of the flat outer surface, i.e., does not reach the surface of the cover substrate. In this way, the deposited laser energy can be completely absorbed by the material of the adjoining substrates involved in the joining process, for example the cover substrate and the second substrate, and an advantageous welding seam or laser bonding line can be produced, which results in an enhanced shear strength of the cover substrate.

A further improvement that can be achieved by thoroughly selecting T is that the zone of non-linear absorption (nlA; i.e., in particular the target point of the laser) does not extend into the cover substrate. It has been found that foreign particles may be generated at the target point by the laser, which may become apparent by a blackening and/or a change in the refractive index in the nlA, for example.

Surprisingly, it is possible in this way to produce a laser bonding line with a particularly large width at the flat outer surface after the material ablation.

The hermetically tight sealing of the package can be accomplished using a laser welding process. The hermetically tight sealing of the cavities or the package can be accomplished at a temperature that is lower or higher than the temperature during later use of the package.

The at least two substrates are optionally provided in the form of a wafer stack in the method, in order to jointly produce a plurality of hermetically sealed packages from the wafer stack in one and the same workflow process, for example.

The method may also include the separating of the package from a wafer stack, and this step is in particular performed by a laser cutting or laser separating step. In particular, the same laser that is also used for the joining step can be used for the separation.

The method described above allows to produce a package with a hermetically sealed accommodation cavity enclosed therein.

A package produced according to the above method can also be used as a medical implant or as a sensor.

The present invention also encompasses a sensor unit and/or a medical implant including a package as described above or including a substrate assembly as also described above.

The height HL of the laser bonding line is optionally in a range of greater than 10 μm, optionally greater than 50 μm, greater than 100 μm, or even greater than 200 μm.

### BRIEF DESCRIPTION OF THE DRAWINGS

The above-mentioned and other features and advantages of this invention, and the manner of attaining them, will become more apparent and the invention will be better understood by reference to the following description of embodiments of the invention taken in conjunction with the accompanying drawings, wherein:

FIG. 1 shows a sectional view through a first embodiment of a package according to the present invention;

FIGS. 2a, 2b show examples of results obtained by disadvantageous fabrication processes;

FIG. 3 illustrates exemplary method steps for producing a package according to the present invention;

FIGS. 4a, 4b show detailed sectional views of the joining zone;

FIG. 5 shows a plan view of a package according to the present invention;

FIG. 6 is a sectional side view through the joining zone;

FIGS. 7a, 7b, 7c, 7d show different configurations of a substrate assembly or package according to the present invention;

FIG. 8 shows a further embodiment of a package according to the present invention;

FIG. 9 is a schematic diagram of a joining zone;

FIGS. 10a, 10b illustrate different versions of laser bonding lines;

FIG. 11 is a photograph of a package that can be produced according to the present invention;

FIG. 12 is a plan view of a package according to the present invention;

FIG. 13 is a sectional side view of the package shown in FIG. 12;

FIG. 14 is a side elevational view of the package shown in FIG. 12;

FIG. 15 is a top plan view of the package shown in FIG. 12;

FIG. 16 is a sectional side view of a laser welding zone with a plurality of parallel laser welding lines prior to material ablation from the cover substrate;

FIG. 17 is a sectional side view of a laser welding zone with a plurality of parallel laser welding lines after material ablation from the cover substrate;

FIG. 18 is a gray scale key for FIGS. 19, 20, and 21;

FIG. 19 is a sectional side view after polishing the surface of the cover substrate;

FIG. 20 shows an analysis result prior to the polishing of the surface of the cover substrate;

FIG. 21 shows an analysis result after the polishing of the surface of the cover substrate;

FIG. 22 shows a further analysis result prior to the polishing of the surface of the cover substrate; and

FIG. 23 shows a further analysis result after the polishing of the surface of the cover substrate.

Corresponding reference characters indicate corresponding parts throughout the several views. The exemplifications set out herein illustrate embodiments of the invention, and such exemplifications are not to be construed as limiting the scope of the invention in any manner.

### DETAILED DESCRIPTION OF THE INVENTION

FIG. 1 shows a sectional side view of an embodiment of a package according to the present invention. Package 1 includes a first substrate 3 in the form of a thin glass layer 3 and a second substrate 24, the first substrate 3 and the second substrate 24 being joined circumferentially in a hermetically tight manner by joining zone 6. A flat outer surface 4 of the first substrate 3 faces the environment. Joining zone 6 has been introduced in the contact area 10 between the first substrate 3 and the second substrate 24. Package 1 encloses a cavity 2 in which an accommodation item 5 is disposed. For example, the cavity 2 was abrasively introduced into the second substrate 24, i.e., hollowed out from the second substrate 24.

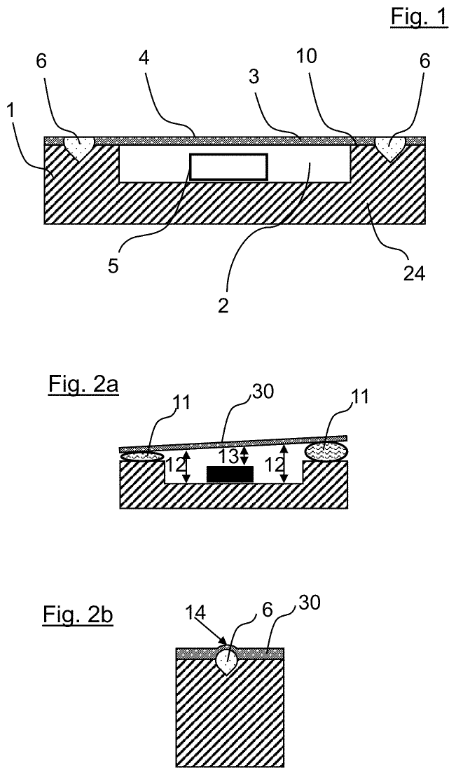

Referring to FIG. 2a there is shown an embodiment that does not represent the present invention but rather illustrates the bonding of two substrates together by way of an adhesive or frit. The problem here is that the bonding areas cannot be realized equidistantly, but rather the adhesive or frit 11 will vary or will be subject to variations in terms of its thickness in the finished product. In this case, either hermetic sealing will not be achieved, or the cover 30 will not be supported flat or leveled, resulting in a poorer bond overall and also in inferior long-term durability of the cover. The arrows 12 exemplify the distance from the bottom of the illustrated cavity to the cover 30, which is not consistent inside the cavity. Arrow 13 indicates the distance from the upper surface of an item inside the cavity to the cover 30.

Referring to FIG. 2b there is shown another inferior implementation that does not represent the present invention. Here, a bulge 14 is visible in the cover 30, which will arise in the case of a common ultrashort pulse process, for example. The drawback hereof is that the upper surface of the cover 30 is not plane or flat and that such a bulge 14 is extremely difficult to rework subsequently. As a result, this involves higher costs, or the product shown in FIG. 2b cannot be employed for the fields of application for which the invention is intended.

FIG. 3 shows exemplary steps for producing a package 1 according to the present invention. A plurality of packages 1 are produced from common substrates of a substrate stack 9, for example in the form of wafers, in the same processing step in order to reduce production costs and minimize material waste. In a preparation step 110, the stack consisting of substrates 7, 24 and the accommodation item 5 are prepared for completion of the package 1. Prior to the final processing, the first substrate 7 has a thickness of more than 200 μm, so that the subsequent joining process can be performed more easily and more precisely. In other words, the substrate is not yet a thin film substrate before the joining process is carried out. Second substrate 24 and first substrate 7 form the wafer stack 9.

In the joining step 120, the joining zone or laser bonding line 6 is introduced into the package 1 using a laser, and in this example the wafer stack 9 has a plurality of cavities 2, namely three cavities 2. Later, a plurality of packages 1 are separated from the wafer stack 9. A laser bonding line 6 is introduced circumferentially around each cavity 1 and seals the respective cavity 2 in a hermetically tight manner.

In a reduction step 130, prior to the final fabrication, the first substrate 7 is processed to obtain the finished cover substrate 3 in the form of a thin glass layer, for example by abrasive material ablation. This may involve a polishing step or a sandblasting step or similar ablation in order to reduce the thin film substrate 3 to a thickness of less than 200 μm. In ablation step 130, the laser bonding line 6 is ablated as well, at least partially, so that the laser bonding line 6 forms part of the surface 4 of the thin glass layer 3, so that an adapted joining zone 6a is formed. The cover substrate 3 is adjusted thereby so as to exhibit particularly high shear strength in its state when bonded to the second substrate 24.

Optionally, the method for producing the package 1 according to the present invention may include a finishing or deposition step 140, for example including a deposition 20 in which an external functional layer 16 is applied to the outer surface 4 of the first substrate 3. In separation step 150, the individual packages 1 are separated using a cutting tool 22, which may be a laser as well, for example the laser that is also employed for joining the package. In other words, a plurality of packages 1 are separated from the wafer stack 9. Thus, a plurality of packages 1 are jointly produced in this example, which means that the costs of the fabrication process can be further reduced.

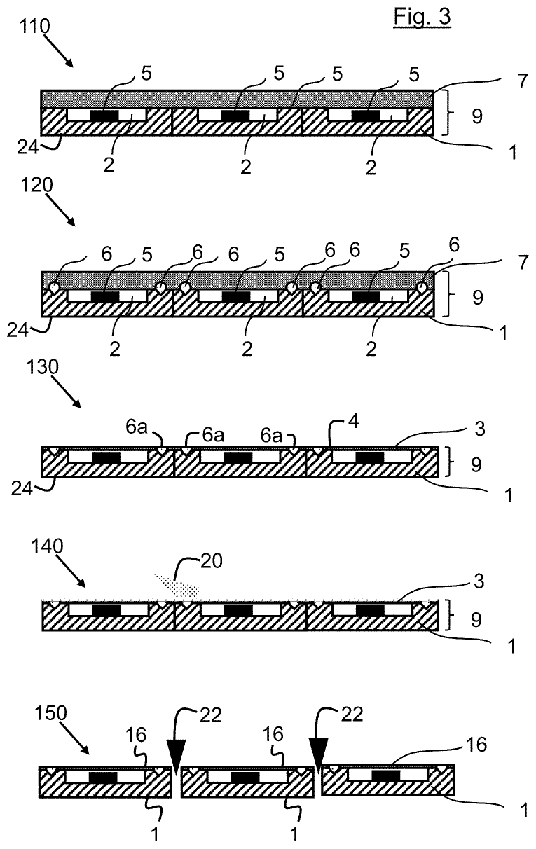

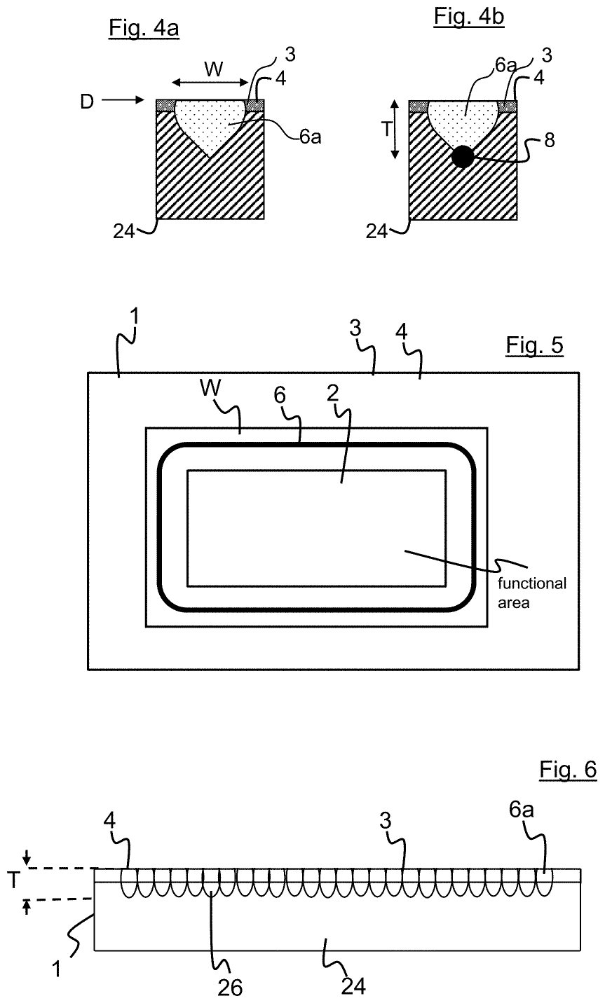

Referring to FIG. 4a there is shown a detail of a longitudinal sectional view through the laser welding zone 6 is, the laser welding zone reaching up to the flat outer surface 4 of the first substrate 3 and having a width W at the flat outer surface 4. The first substrate 3 has a thickness D, for example less than 200 μm. In the present example, the thickness of the first substrate 3 may be less than 100 μm, less than 70 μm, optionally less than 50 μm, or even less than 30 μm. The width or diameter of the laser bonding line 6, denoted by W here, is greater than the thickness of the thin glass layer 3. For example, W is 200 μm, and the thickness of the thin glass layer is 130 μm. Furthermore, by way of example, W/D is greater than 1, so that the width of the laser bonding line 6 at the outer surface 4 is greater than the thickness D of the thin glass layer 3. Optionally, the ratio W/D is 0.5, so that W is half the thickness D of the thin glass layer 3 or greater. The W/D ratio may also be greater than or equal to 0.1, more optionally greater than or equal to 0.05.

In terms of width, typical current laser bonding lines are in a range from 10 μm to 50 μm. A W/D of 0.05 would be obtained with W=10 μm and D=200 μm, for example. But larger values of W/D can also be useful, for example 0.25, which is obtained by W=50 μm and D=200 μm.

The method of the present invention, in which the thin glass layer 3 is produced by ablation during the fabrication process, among other things, results in a particularly useful finish of the flat outer surface 4, in particular without any bulges or bumps protruding beyond the outer surface 4 in addition to the average thickness D of the thin glass layer 3.

Referring to FIG. 4b where, in addition to FIG. 4a, the target area 8 of the welding laser is indicated, which is introduced at a depth T measured from the outer surface 4. For example, T may be greater than or equal to 10 μm, greater than or equal to 50 μm, greater than or equal to 100 μm, or even greater than or equal to 200 μm. T is always greater than the thickness D of the thin glass layer, in order to join the first substrate 3 and the second substrate 24 in a hermetically tight manner. Target site 8 represents the area of non-linear absorption in the material and/or of avalanche ionization, i.e., the depth that is set for the Keldysh parameter, for example. It is the area of the laser bonding line where an optical defect is introduced, i.e., a locally changed refractive index or blackening, for example.

Referring to FIG. 5 there is shown a plan view of a package 1 according to the present invention, with a functional area 2 provided inside the package 1. The laser bonding line 6 extends circumferentially around the functional area 2 and seals the functional area 2, which is in the form of a cavity here, in a hermetically tight manner on all sides. The width of laser bonding line B at the outer surface 4 of the first substrate 3 is given around the laser bonding line 6, by way of example.

Referring to FIG. 6 there is shown a sectional side view through a package or substrate assembly according to the present invention along a laser bonding line 6. The laser bonding line 6 has been modified at the upper surface to present the adapted joining zone 6a which forms part of the outer surface 4 of the first substrate. Here, the laser bonding line 6 extends both into the first substrate 3 and into the second substrate 24.

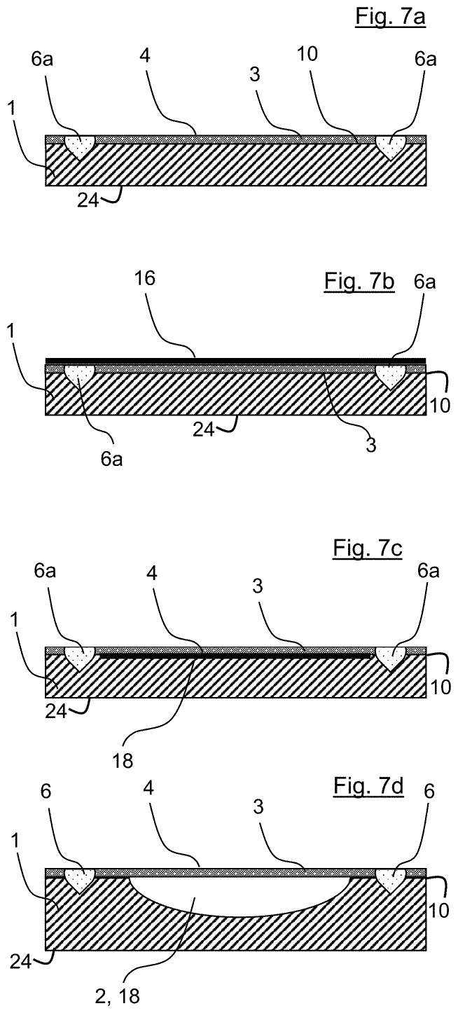

Referring to FIG. 7a there is shown a substrate assembly according to the present invention, including a thin film substrate 3 and a second substrate 24 bonded thereto in a hermetically tight manner, which are joined in a hermetically tight manner by the laser bonding line 6.

Referring to FIG. 7b there is shown the assembly of FIG. 7a which additionally has an external functional layer 16, for example an optical coating 16. The external functional layer 16 has a consistent, i.e., uniform thickness and also covers the modified functional layer 6, 6a. The laser bonding line 6 is introduced in the contact area 10 between the first and second substrates 3, 24.

Referring to FIG. 7c there is shown the assembly of FIG. 7a with an additional inner functional layer 18 or an inner functional area 18 which is integrated in the second substrate 24, for example, or is disposed between the first substrate 3 and the second substrate 24, or may be applied on the lower surface of the first substrate 3. This layer 18 may form part of the contact area or may define the contact area. Layer 18 may, for example, be an AR coating on the inner surface of cover substrate 3. If the layer 18 is formed over the entire surface, it will be damaged in the area of laser bonding line 6, 6a. This can be tolerated if the functionality of the layer 18 is not impaired thereby, for example if the coating is retained inside the cavity 2.

Referring to FIG. 7d there is shown yet another embodiment in which the package 1 encloses a cavity 2 or a functional area 18. Functional area 18 may be a lens-shaped recess in the second substrate 24 which may already have optical properties due to the shape of the recess, for example, which means it may function as a lens, for example.

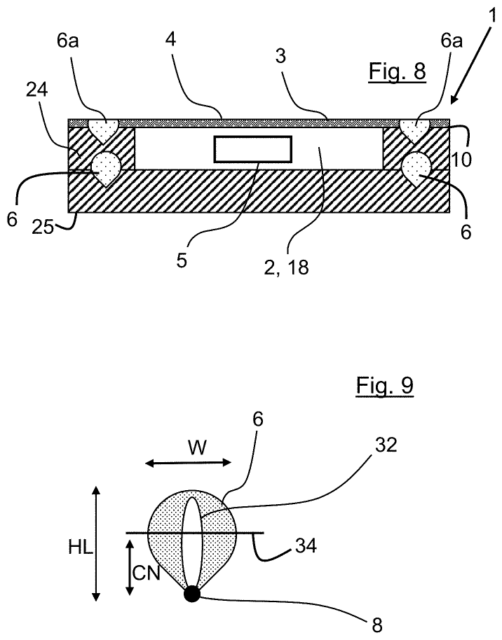

FIG. 8 shows a further embodiment of the package 1, in which the second substrate 24 is joined with a third substrate 25 in a hermetically tight manner by a first laser bonding line 6, and the second substrate 24 is joined with the first substrate or cover substrate 3 by a second laser bonding line 6a. In this example, the two laser bonding lines 6, 6a are arranged directly one above the other. Although this arrangement has advantages, the present invention should not be limited to this arrangement. Among the advantages of this arrangement is the desired maximized size of the cavity 2 as a percentage portion of the package. The laser bonding line optionally keeps a minimum distance from each interface or surface surrounding the laser bonding line 6, 6a. The advantageous arrangement of the two laser bonding lines 6, 6a directly one above the other or offset as little as possible from one another comes as a result of the reasoning that, on the one hand, the cavity 2 should be the closest possible to the outer surface of the package 1 and, on the other hand, the laser bonding lines 6, 6a should keep a minimum distance both to the cavity 2 and to the outer surface of the package 1. Laser bonding line 6a has a flattened upper side, which is a result of the abrasive thinning of the cover substrate 3 following the joining process in order to form the outer surface 4 of the cover substrate 3. Material from the laser bonding line 6a is also removed in this process.

FIG. 9 is a schematic diagram of the structure of a laser bonding line 6, 6a. W denotes the maximum (lateral) width of fusion zone 36, and plane 34 represents the plane in which W is measured. HL is the height of fusion zone 36, and CN is the distance from the laser focus, i.e., from the area of non-linear absorption, to the plane 34 in which W is measured. Inside laser bonding line 6, 6a, an inner melting zone 32 is defined.

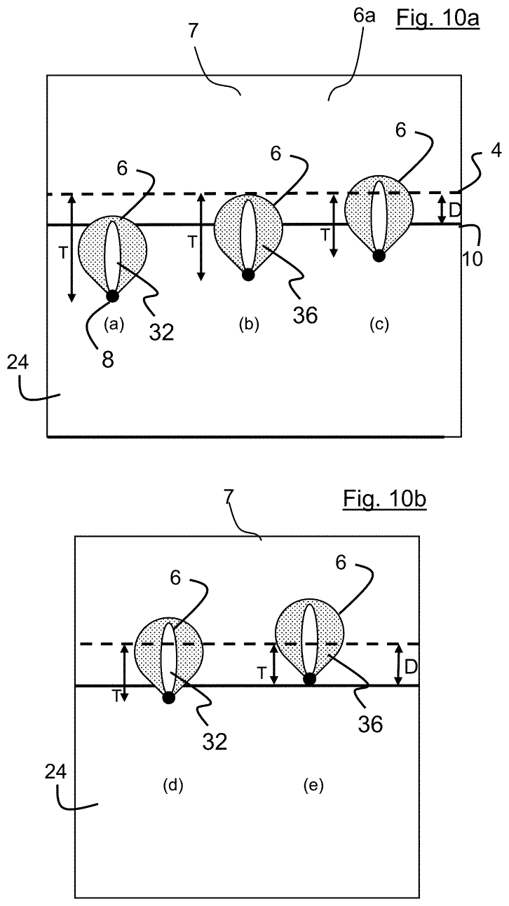

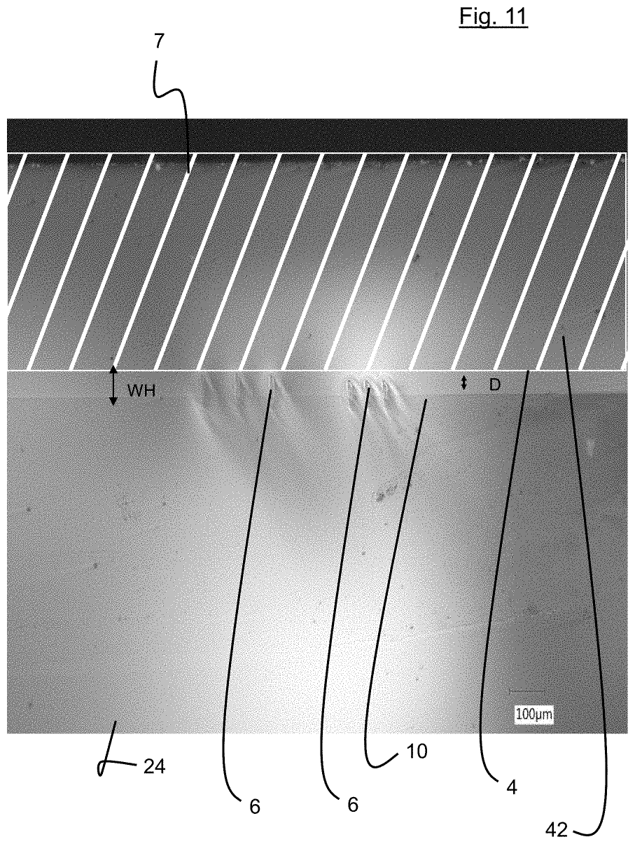

Referring to FIGS. 10a and 10b there is shown a comparison of different depths T of exemplary laser welding zones 6, 6a denoted by letters (a), (b), (c), (d), and (e), which are in part introduced into a raw substrate 7, i.e., thin-film substrate 3, before the material ablation. Laser welding zones 6, 6a differ in terms of the depth T at which they are introduced from above through the first substrate 7 into the substrate stack 1 or the package 1. The later outer surface 4 is indicated in dashed lines; this plane is intended to define the flat outer surface 4 on the final package. The depths T are measured as the distance between the focus point 8 and the later flat outer surface 4. D designates the thickness of the cover substrate 3 after the final treatment. In the case of the laser bonding line 6, 6a denoted by (a), the melting zone 36 only barely extends into the cover substrate 3. Although this assembly already provides a sufficient bond, it has been found that such an assembly might be sensitive to potential material defects, so that a material defect or weakening of one of the substrates 3, 24, 25 could result in the cover substrate becoming detached or the hermetically tight sealing becoming corrupted.

In the case of the laser bonding lines 6, 6a designated (b), (c), and (d), the convection zone 36 extends sufficiently far into the cover substrate 7, i.e., into the later thin-film substrate 3, and in cases (c) and (d) material from the melt bubble 36 will already be removed for producing the thin-film substrate 3. However, in the case of the laser bonding line 6, 6a denoted (d), the zone of non-linear absorption 8 is already clearly close to the contact area 10 between substrates 3, 24. In the zone of nonlinear absorption 8, a visible material modification with turbidity of the material and/or change in the refractive index has been observed. It is therefore optional to keep the laser target area 8 spaced apart from the contact area 10, which is still the case in the embodiments (a), (b), and (c). Also in those cases, sufficient material from the two substrates 3, 24 is convectively mixed with one another. Finally, the embodiment denoted (e) shows a laser bonding line 6, 6a which no longer extends into the second substrate 24 and is no longer able to produce a bond between the two substrates.

Therefore, what turned out to be an optional position of the laser bonding line 6, 6a for producing a thin-film substrate stack or a package 1 is when T equals D+CN. Here, an optional range that can be considered is where T is less than D+WH. On the other hand, it is optional to select T to be greater than CN in order to create a bond between the first and second substrates 3, 24. If the plane 34 of the largest extent W of the melt bubble 36 lies approximately in the middle of the later thin film substrate, i.e., approximately at D/2, then T−CN=D/2 applies approximately. The thin film substrate stack 1 or the package 1 can be successfully produced in all of the aforementioned ranges and at intermediate levels.

Referring to FIG. 11 there is shown a side view of a package 1 or a substrate stack 1, 9, in which a plurality of laser bonding lines 6, 6a have been introduced, by way of example. An upper thickness portion 42, shown hatched, is intended to be removed down to the later flat outer surface 4 for producing the thin film substrate 3. The sufficient material thickness of the upper portion 42 ensures that the laser bonding lines 6, 6a can be introduced into the package 1 or into the substrate stack 1, 9 in a non-influenced or non-disturbed manner and that a reliable bond can be achieved between the thin film substrate 3 and the second substrate 24.

The functional area 18 can serve various tasks, for example it may be or may include an optical receiver or a technical, electromechanical, and/or electronic component, which may be arranged in a cavity 2. As illustrated by FIG. 6, a laser bonding line 6 consists of a plurality of laser pulse impact areas 26 which are placed so close to one another that the material of the second substrate 24 and the material of the first substrate 3 seamlessly fuse to one another.

Referring to FIGS. 12 to 15 there is shown a further embodiment of a package 1 in which a cavity 2 or a functional area 18 is enclosed in the package 1 in a hermetically tight manner. FIG. 12 shows a plan view of the package 1, with the thin cover substrate 3 spanning the cavity 2 on top. The cavity 2 may be shaped irregularly, as in this example, and can be optimized with regard to the installation space or other requirements of the components 5 to be accommodated. The embodiment of the package 1 shown here can be implemented as a pressure sensor 1.

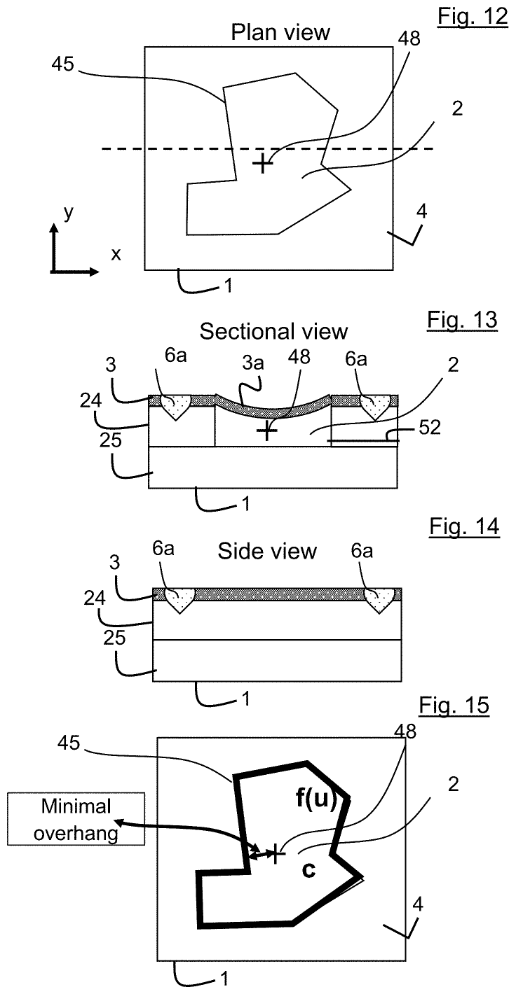

FIG. 13 shows the pressure sensor 1 in a side view. The cover substrate 3 has been thinned or polished to a thickness of approximately 100 to 150 μm, specifically 130 μm in this case. A portion 3a of the cover substrate 3 spans the cavity 2. The cover substrate 3 is thin enough to be able to compensate for pressure fluctuations or pressure values with a deformation in the self-supporting or overhanging portion 3a. The deformation of the self-supporting portion 3a, in turn, can be detected by an optical measurement, for example, and from this, an absolute pressure value, a relative pressure value, or a pressure change can be derived, for example.

The structure including the cover substrate 3, for which first a thicker substrate is joined, i.e., welded, to the second substrate 24 and after the laser welding the cover substrate 3 is thinned to the desired thickness, for example by polishing, is able to provide an even stronger or more useful cover substrate 3, which can withstand greater pressure differences between the interior of the cavity 2 and the environment without being destroyed. This is in particular because the step of removing material from the cover substrate 3 reduces material stresses in the cover substrate 3 and thereby improves the strength and/or deformability of the cover substrate 3. The hermetic sealing of the cavity 2 by the circumferential laser bonding line 6a which completely encloses the cavity 2 is a key feature for ensuring that pressure differentials between the interior of the cavity 2 and the environment are reliably maintained and pressure measurements can be executed reliably.

The flexibility K of the cover substrate 3 within the borders of cavity 2 which is covered by the portion 3a of the cover substrate 3 also allows to implement optical properties, if the portion 3a is considered as a lens or as generally having optical properties. On the one hand, this allows to optically measure the prevailing pressure or pressure differential, since the optical properties of the portion 3a change with increasing deflection. On the other hand, it is possible to set a desired optical property by adjusting a pressure or pressure differential. For example, it is possible to focus an optical system, i.e., to adjust the focal point of the portion 3a. For example, an optical sensor may be disposed inside the cavity 2 and the optical focus of the radiation that is incident in the cavity 2 could be varied by pressure changes. For this purpose, an adjustable passage 52 may also be provided, by way of which pressure equalization and/or a pressure change can be achieved in the interior of the package 1 or in the cavity 2. For example, a pump or a valve can be arranged at or in the passage 52 for this purpose. For example, a liquid might also be disposed in the interior or in the cavity 2, and the optical properties of the portion 3a can be adjusted by inflow or outflow of liquid through the passage 52.

The second substrate 24 may either be a continuous substrate 24, for example consisting of a wafer which has “holes” or recesses at the sites of the later cavities 2, or spacers can be used between the first substrate 3 and the third substrate 25. Finally, FIG. 14 shows the package in a side view, illustrating the layer assembly consisting of the three layers 3, 24, 25.

Referring to FIG. 15 another relationship is explained. The continuous or discrete (with a number U of points) 2D function of points f(u) describes the border of the cavity 2 or the functional area 18. With D as the thickness of the cover substrate 3, a factor K can be defined as follows:

$$K = \frac{min ( \sqrt{{( {f}_{x} ( u ) - {c}_{x} )}^{2} + {( {f}_{y} ( u ) - {c}_{y} )}^{2} )}}{D}$$

where c corresponds to the coordinates of the center 48, or barycenter, of cavity 2 and can be obtained as follows:

\vec{c}=∫\vec{f}du

or in the discrete case:

$$\vec{c} = \frac{1}{U} {\sum }_{u} \vec{f}$$

The factor K provides a measure for estimating or calculating the flexibility of the cover substrate 3. The flexibility K is then optionally in the range from 5 to 15, optionally in the range from 7 to 12.

In one example, with a thickness of the cover substrate of 150 μm, the K value can then be obtained as K=1.25 mm/0.15 mm=8.33.

In other words, the package 1 has a flexibility K with regard to the cover substrate, with a calculated value for the flexibility of K≥3, optionally K≥5, optionally K≥7, and/or with K≤18, optionally K≤15, and optionally K≤12. Possible intervals for the flexibility of a cover substrate 3, which were found to be advantageous within the context of the invention, are then 3≤K≤18, optionally 5≤K≤15, or optionally 7≤K≤12, while the other combinations of figures for the range of values of K can also be advantageous.

FIGS. 16 to 23 relate to a further embodiment of a package 1, which clearly illustrates the surprising improvement in terms of the internal stresses in the material of the cover substrate 3. FIG. 16 shows a cross-sectional view through a package 1 prior to the ablation of material from the cover substrate 7. For test purposes, in order to better identify the material stress, a plurality of laser welding lines 6 has been introduced into the material assembly consisting of the cover substrate 7 and the base substrate 24 parallel and more or less equidistant from one another. Prior to the final processing, the cover substrate 7 initially has a thickness of 1800 μm, thus corresponding to the thickness of the base substrate 24 which also has a thickness of 1800 μm. The cover substrate 7 is ablated, for example by abrasive polishing or else by sandblasting, down to the indicated reduction line 135, and thus becomes the thin cover substrate 3, for example a thin glass layer. The reduction line 135 thus corresponds to an ablation target. In this case, a residual thickness of 100 μm is set as the ablation target 135 for the cover substrate 3, so that the package will still have a total thickness of 1900 μm.

The laser welding lines 6 extend into the two substrates 7, 24 to approximately the same depth, and the shape of the laser welding lines 6 has been explained and illustrated in detail in conjunction with FIGS. 4a, 4b, 9, 10a, and 10b. The features of the laser welding lines as illustrated in the aforementioned figures are inherently also present in FIGS. 16 to 23, and it is merely for the sake of greater clarity that not all of the reference numbers are repeated in these figures. The target point of the laser focus is in the base substrate 24, and so the site of non-linear absorption 26 is located there. The convection zone 36 extends from the base substrate 24 into the cover substrate 7, and in the convection zone 36 material from the base substrate 24 mixes with material from the cover substrate 7.

As a result, a non-releasable bond is obtained between the two substrates 3, 24 joined together. At the same time, as already mentioned above, the laser welding lines 6 can be produced reliably if the cover substrate 7 has a greater thickness prior to the final processing, since material burn-off will be prevented in this way and a complete and coherent exchange of material will occur in the convection zones 36. Subsequently, the material ablation 130 from the cover substrate 7 will be accomplished.

FIG. 17 shows the package 1 with the ablated cover substrate 3, whereby modified laser welding lines 6a have been produced. The cover substrate 3 has been ablated down to the ablation target 135, i.e., it has a thickness of 100 μm. The base substrate still has a thickness of 1800 μm (accordingly, the drawing is not true to scale in relation to FIGS. 19 to 23, since the cover substrate 3 would hardly be visible on the exact scale). As can be seen from FIG. 17, a substantial proportion of the outer surface 4 of the cover substrate 3 is defined by the modified laser welding lines 6a in this example, which extend as far as to the outer surface 4. The structure of the embodiment of FIG. 17 also corresponds to the measurement results shown in FIGS. 19 through 23.

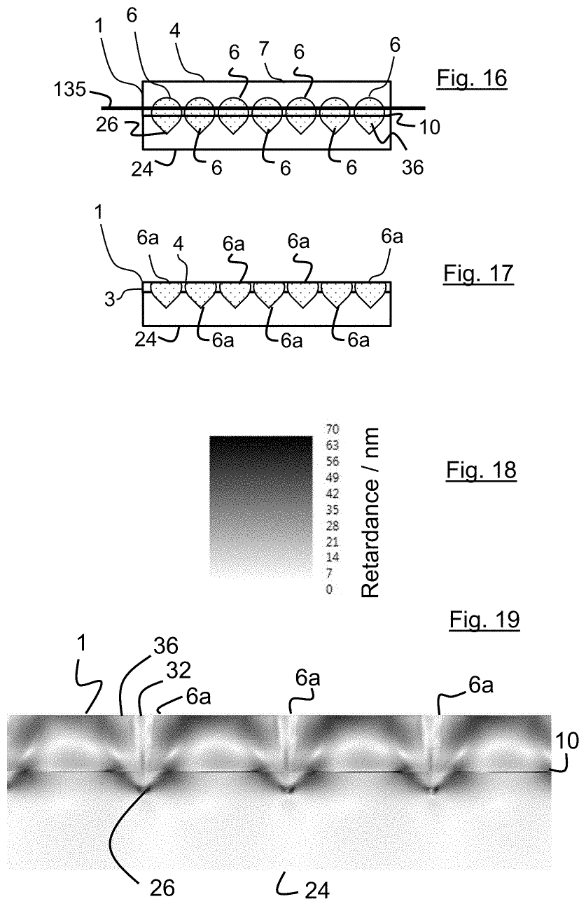

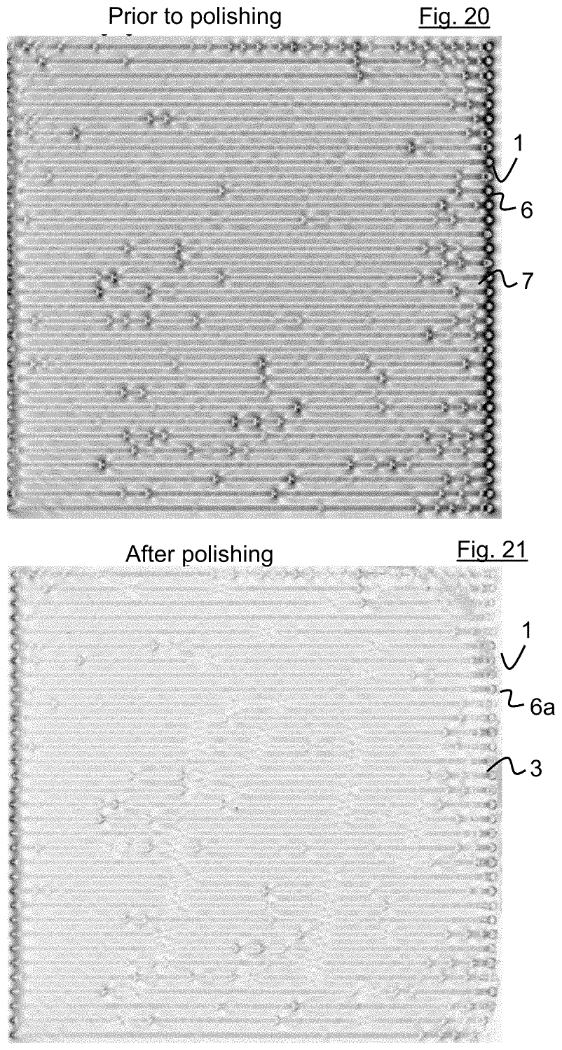

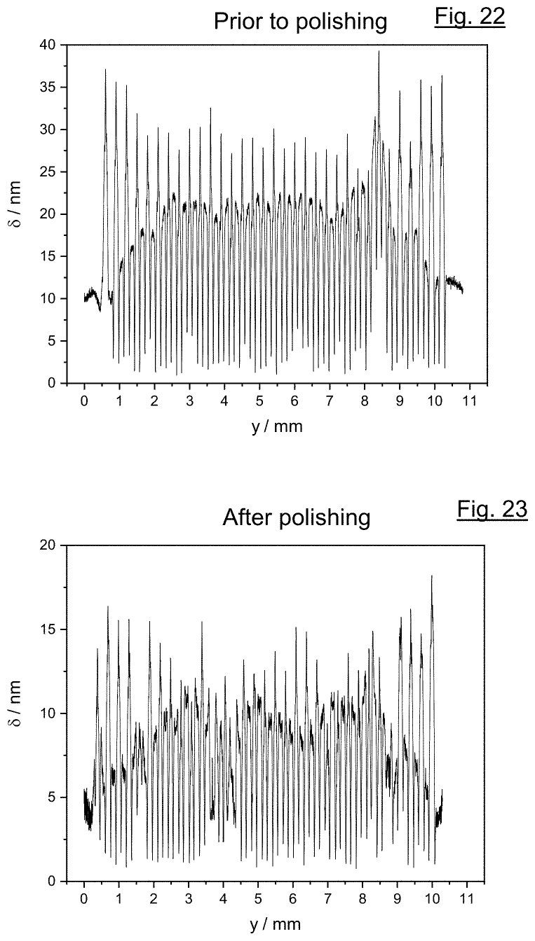

Referring to FIG. 18 which shows a grayscale which serves to associate a retardance value with the gray levels shown in FIGS. 19, 20, and 21. For FIGS. 20 and 21, the scale ranges from a retardance of 0 nm for white to 70 nm for black, and the range of values between the values from 0 to 70 nm is resolved linearly. In the case of FIG. 19, the white value also corresponds to 0 nm, whereas black corresponds to a retardance of 180 nm. The retardance range from 0 to 180 nm in the view of FIG. 19 is also resolved linearly over the gray levels shown, from white to black.

Referring to FIGS. 19, 20, and 21 there are shown representations of retardance measurements of a joined and, in the case of FIGS. 19 and 21 polished, package 1. The package 1 as shown in FIG. 20 corresponds to the cross-sectional view of FIG. 16 in terms of its structure, and the representation shown in FIG. 21 corresponds to the cross-sectional view of FIG. 17 in terms of its structure. The plurality of adjacent laser welding lines 6, 6a is clearly visible in FIGS. 19, 20, 21. Retardance refers to the delay that occurs for example in a birefringent crystal or other birefringent medium between the two perpendicularly polarized light beams. As explained above, it can provide information about the flexibility K of the cover substrate 3 in the present case.

FIG. 19 shows a cross-sectional view through the package 1, illustrating the retardance measured in the material. The laser bonding lines 6a with the laser target points, i.e., the non-linear absorption area 26, the inner melting zone 32 and the convection zone 36 are already clearly recognizable from the retardance. The contact area 10 between the cover substrate 3 and the base substrate 24 is also recognizable. Even areas that previously had high retardance values are homogenized in the sanded substrate 3 of the package 1 over a number of laser bonding lines 6a.

A direct comparison between the views of FIGS. 20 and 21 reveals that FIG. 20 is significantly darker, i.e., it has a greater retardance. What can be concluded therefrom is that the material of the cover substrate 3 of the package 1 shown in FIG. 20 has a greater residual stress or intrinsic stress than after the material ablation, the latter state being shown in FIG. 21. The same relationship becomes furthermore obvious from the two graphs of FIGS. 22 and 23, in which the obtained retardance values are plotted across a cross section of the package 1. As becomes clear, the intrinsic stress which has an influence on the basis of the measured retardance values, can be reduced by a factor of approximately 2 after the material ablation down to the ablation target 135. That means, in the case prior to material ablation as shown of FIG. 22, the retardance as measured is approximately twice as great as in the case after material ablation as shown in FIG. 23.

It will be apparent to a person skilled in the art that the embodiments described above are meant to be exemplary and that the invention is not limited thereto but may be varied in many ways without departing from the scope of the claims. Furthermore, it will be apparent that irrespective of whether disclosed in the description, the claims, the figures, or otherwise, the features individually define essential components of the present invention, even if they are described together with other features. Throughout the figures, the same reference numerals designate the same features, so that a description of features that are possibly only mentioned in one or at least not in conjunction with all figures can also be transferred to such figures with regard to which the feature has not explicitly been described in the specification.

### LIST OF REFERENCE NUMERALS

1 Package or substrate assembly
2 Functional area or cavity
3 First substrate or cover substrate or thin glass layer or cover
3a Deformable or resilient portion of cover substrate
4 Outer surface or outer flat surface of first substrate
5 Accommodation item
6 Joining zone or laser bonding line
6a Adapted joining zone
7 First substrate (prior to final processing)
8 Target area of welding laser
9 Wafer stack
10 Contact area or contact plane
11 Adhesive or glass frit
12 Distance from bottom of cavity to the cover
13 Distance from upper surface of accommodation item to the cover
14 Bulge
16 Optical finish or outer functional layer
18 Inner functional layer or functional area
20 Deposition of outer functional layer
22 Cutting tool
24 Second substrate
25 Third substrate
26 Laser pulse impact area, area of nonlinear absorption (nlA)
30 Cover
32 Inner melting zone
34 Plane of largest lateral extent of the melting area of the laser welding zone
36 Convection zone, elongated weld bubble
42 Upper thickness portion
45 Border of cavity 2 or of functional area 18
48 Center of inner space or barycenter of cavity 2
52 Passage
110 Preparation step
120 Joining step
130 Reduction step
135 Reduction line or ablation target
140 Finishing or deposition step
150 Separation step
W Diameter of laser welding zone at outer surface 4
D Thickness of first substrate 3
T Height of laser welding zone in package 1
HL (WH) Height of laser bonding line

While this invention has been described with respect to at least one embodiment, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A hermetically sealed package, comprising:
at least one cover substrate which is sheet-like and includes a flat outer surface and a circumferential narrow side, the at least one cover substrate being formed as a transparent thin film substrate, the at least one cover substrate having a thickness of less than 200 μm;
a second substrate which is adjoined to the at least one cover substrate and in direct contact with the at least one cover substrate;
at least one functional area enclosed by the hermetically sealed package, the at least one functional area being between the at least one cover substrate and the second substrate; and
a laser bonding line which joins the at least one cover substrate and the second substrate directly and in a hermetically tight manner.

2. The hermetically sealed package of claim 1, wherein at least one of:
(a) the thickness of the at least one cover substrate is measured on the circumferential narrow side of the at least one cover substrate; and
(b) at least one of (i) the at least one cover substrate has a thickness of less than 170 μm, and (ii) a thickness of more than 10 μm.

3. The hermetically sealed package of claim 1, wherein the laser bonding line has a width W in a direction parallel to a main extension direction of the at least one cover substrate, and wherein the at least one cover substrate exhibits an increased shear strength when bonded to the second substrate.

4. The hermetically sealed package of claim 3, wherein at least one of:
(a) the width W of the laser bonding line is greater than the thickness—that is, a thickness D—of the at least one cover substrate; and
(b) a ratio between the width W of the laser bonding line and the thickness—that is, a thickness D—of the at least one cover substrate—that is, W/D—is greater than or equal to 1.

5. The hermetically sealed package of claim 1, wherein at least one of:
(a) the laser bonding line has an initial height HL, and the thickness of the at least one cover substrate is less than half of the initial height HL; and
(b) at least one of (i) T<D+WH, and (ii) T>CN, wherein T is a height of the laser bonding line, D is the thickness of the at least one cover substrate, WH is a thickness of the laser bonding line in a direction perpendicular to a planar extension direction of the at least one cover substrate, and CN is a distance from a laser focus to a plane in which a width W of the laser bonding line is measured.

6. The hermetically sealed package of claim 1, wherein the flat outer surface has at least one of the following features:
a coating layer;
a nano-print or a nano-embossment; and
an additional functional area.

7. The hermetically sealed package of claim 1, wherein at least one of:
(a) the flat outer surface of the at least one cover substrate is distinguished by being flat; and
(b) the at least one cover substrate is thinner than 200 μm across an entire extent of the at least one cover substrate.

8. The hermetically sealed package of claim 1, wherein the at least one cover substrate and the second substrate define a contact plane or a contact area where the at least one cover substrate contacts the second substrate, wherein the contact plane or the contact area is free of any foreign materials.

9. The hermetically sealed package of claim 1, wherein:
(a) the second substrate is a base substrate, which is hermetically joined to the at least one cover substrate by the laser bonding line; or
(b) the hermetically sealed package includes a base substrate, the second substrate being an intermediate substrate which is disposed between the at least one cover substrate and the base substrate, the base substrate being joined to the intermediate substrate along a first bonding plane, and the at least one cover substrate being joined to the intermediate substrate along a second bonding plane.

10. The hermetically sealed package of claim 1, wherein the laser bonding line has a thickness WH in a direction perpendicular to a planar extension direction of the at least one cover substrate; and wherein the laser bonding line extends as far as to the flat outer surface.

11. The hermetically sealed package of claim 1, wherein at least one of the at least one cover substrate and the second substrate include a material modification in an area associated with the laser bonding line.

12. The hermetically sealed package of claim 1, wherein the functional area includes a hermetically sealed accommodation cavity configured for accommodating an accommodation item.

13. The hermetically sealed package of claim 1, wherein the at least one cover substrate is transparent for a range of wavelengths at least one of at least partially and at least in a section of the at least one cover substrate.

14. The hermetically sealed package of claim 1, wherein:
(1) the at least one cover substrate is made of a glass, a glass ceramic, silicon, sapphire, or a combination thereof; or
(2) the at least one cover substrate is made of a ceramic material.

15. The hermetically sealed package of claim 1, wherein the hermetically sealed package is produced by way of a method which comprises the steps of:
providing the at least one cover substrate and the second substrate, the at least one cover substrate including a transparent material, the at least one cover substrate and the second substrate being arranged so as to directly adjoin each other or on top of one another so that a contact area is defined between the at least one cover substrate and the second substrate, the at least one cover substrate including the flat outer surface and the circumferential narrow side;
sealing a package in a hermetically tight manner by directly joining the at least one cover substrate and the second substrate to one another along the at least one contact area of the package; and
ablating a material from the at least one cover substrate, and thereby producing a thin film substrate from the at least one cover substrate, so that a thickness of less than 200 μm is obtained at the circumferential narrow side thereof.

16. The hermetically sealed package of claim 1, wherein the hermetically sealed package is configured for at least one of a sensor unit and a medical implant.

17. A hermetically joined substrate assembly, comprising:
at least one first substrate which is sheet-like and includes a flat outer surface and a circumferential narrow side, the first substrate being formed as a transparent thin film substrate, the first substrate having a thickness of less than 200 μm;
a second substrate which is adjoined to the first substrate and in direct contact with the first substrate; and
at least one laser bonding line which joins the first substrate and the second substrate directly and in a hermetically tight manner, the at least one laser bonding line extending as far as to the flat outer surface.

18. A method for providing a hermetically sealed package which includes a functional area, the method comprising the steps of:
providing at least one cover substrate and a second substrate, the at least one cover substrate including a transparent material, the at least one cover substrate and the second substrate being arranged so as to directly adjoin each other or on top of one another so that a contact area is defined between the at least one cover substrate and the second substrate, the at least one cover substrate including a flat outer surface and a circumferential narrow side;
sealing a package in a hermetically tight manner by directly joining the at least one cover substrate and the second substrate to one another along the at least one contact area of the package; and
ablating a material from the at least one cover substrate, and thereby producing a thin film substrate from the at least one cover substrate, so that a thickness of less than 200 μm is obtained at the circumferential narrow side thereof.

19. The method of claim 18, wherein the functional area is formed as an accommodation cavity configured for accommodating at least one accommodation item, wherein at least one of:
(1) wherein at least one of (i) the sealing of the package in a hermetically tight manner and (ii) a sealing of the accommodation cavity in a hermetically tight manner is performed by a laser welding process; and
(2) wherein at least one of (i) the sealing of the package in a hermetically tight manner and (ii) a sealing of the accommodation cavity in a hermetically tight manner is performed at a temperature which is lower or higher than a temperature during later use of the package.

20. The method of claim 18, wherein the at least one cover substrate and the second substrate are formed as a wafer stack in order to jointly produce a plurality of the hermetically sealed package from the wafer stack in one and the same workflow process.

21. The method of claim 18, further comprising a step of separating the package from a wafer stack.

22. The method of claim 18, wherein the functional area is formed as an accommodation cavity configured for accommodating at least one accommodation item, wherein the hermetically sealed is used a medical implant or as a sensor.
